(19) United States
(12) Patent Application Publication
(10) Pub. No.: US 2023/0222280 A1
(43) Pub. Date: Jul. 13, 2023

(54) METHOD AND APPARATUS FOR ANALYZING CIRCUIT, ELECTRONIC DEVICE, AND STORAGE MEDIUM

(71) Applicant: CHANGXIN MEMORY TECHNOLOGIES, INC., Hefei City (CN)

(72) Inventor: Shao YOU, Hefei (CN)

(73) Assignee: CHANGXIN MEMORY TECHNOLOGIES, INC., Hefei City (CN)

(21) Appl. No.: 17/810,598

(22) Filed: Jul. 2, 2022

Related U.S. Application Data
(63) Continuation of application No. PCT/CN2022/073937, filed on Jan. 26, 2022.

(30) Foreign Application Priority Data
Jan. 12, 2022 (CN) 202210031057.2

(51) Int. Cl. G06F 30/398; G06F 30/392

(52) U.S. Cl. CPC G06F 30/398; G06F 30/392

(57) ABSTRACT

An apparatus for analyzing a circuit includes: an information module, configured to obtain a plurality of layout cells; an environment configuration module, configured to set, based on types or parameters or combinations of the types and the parameters of the plurality of layout units, a plurality of LPE environments, each corresponding to a respective one of the types, the parameters, or the combinations; and a batch processing module, configured to, for each of the LPE environments, extract parasitic parameter netlists of more than one of the plurality of layout units in the LPE environment in batches.

### CROSS-REFERENCE TO RELATED APPLICATIONS

This is a continuation of International Application No. PCT/CN2022/073937, filed on Jan. 26, 2022, which claims priority to Chinese Patent Application No. 202210031057.2, filed on Jan. 12, 2022. The disclosures of these applications are hereby incorporated by reference in their entireties.

### BACKGROUND

Simulation may include pre-simulation and post-simulation, and the two processes should be included in a complete circuit design.

Pre-simulation refers to functional simulation, with a purpose of analyzing the accuracy of a logic relationship of a circuit, and may observe waveforms of an input/output port of the circuit and any signal and register in the circuit as required. As relatively ideal simulation, pre-simulation does not include any physical information (such as a parasitic effect and an interconnection delay), and thus is fast.

Post-simulation refers to back-annotating a parasitic parameter and an interconnection delay into an extracted circuit netlist for simulation and analyzing a circuit to ensure that the circuit meets a design requirement. Except the addition of the parasitic parameter and the interconnection delay, a method for post-simulation is much the same as that for pre-simulation. Post-simulation is much slower than pre-simulation.

In the related art, with the constant increase of a scale of an integrated circuit, the number of transistors on a chip increases constantly. As a result, the numbers of parasitic resistances and capacitances increase enormously, more time is needed by the post-simulation of the circuit, circuit verification time is prolonged, and furthermore, a design cycle and delivery time of the chip are affected to some extents.

### SUMMARY

The disclosure relates to the technical field of semiconductors, in particularly to a method and apparatus for analyzing a circuit, an electronic device, and a storage medium.

According to a first aspect, an embodiment of the disclosure provides an apparatus for analyzing a circuit, including: an information module, configured to obtain a plurality of layout cells; an environment configuration module, configured to set, based on types or parameters or combinations of the types and the parameters of the plurality of layout units, a plurality of Layout Parasitic Extraction (LPE) environments, each corresponding to a respective one of the types, the parameters, or the combinations; and a batch processing module, configured to, for each of the LPE environments, extract parasitic parameter netlists of more than one of the plurality of layout units in the LPE environment in batches.

According to a second aspect, an embodiment of the disclosure provides a method for analyzing a circuit, including: obtaining a plurality of layout units; setting, based on types or parameters or combinations of the types and the parameters of the plurality of layout units, a plurality of LPE environments, each corresponding to a respective one of the types, the parameters, or the combinations; and for each of the LPE environments, extracting parasitic parameter netlists of more than one of the plurality of layout units in the LPE environment in batches.

According to a third aspect, an embodiment of the disclosure provides an electronic device, including: a memory, configured to store a computer program; and a processor, configured to execute the computer program in the memory to implement the operations of any method in the second aspect.

According to a fourth aspect, an embodiment of the disclosure provides a computer-readable storage medium having stored thereon a computer program that, when executed by a processor, implements the operations of any method in the second aspect.

### BRIEF DESCRIPTION OF THE DRAWINGS

In the drawings, unless otherwise specified, the same reference numerals throughout multiple drawings represent the same or similar components or elements. These drawings are not necessarily drawn to scale. It is to be understood that these drawings only show some implementations of the disclosure and should not be considered as limits to the scope of the disclosure.

FIG. 1 is a schematic diagram of program modules of an apparatus for analyzing a circuit according to an embodiment of the disclosure.

FIG. 2 is a schematic diagram of a circuit analysis process according to an embodiment of the disclosure.

FIG. 3 is a schematic diagram of an implementation process of a method for analyzing a circuit according to an embodiment of the disclosure.

FIG. 4 is a schematic diagram of an implementation process of a parasitic parameter extraction method according to a specific example of the disclosure.

FIG. 5 is a schematic diagram of a hardware structure of an electronic device according to an embodiment of the disclosure.

### DETAILED DESCRIPTION

In order to solve the problems in the related art at least to some extents, the disclosure provides a method and apparatus for analyzing a circuit, an electronic device, and a storage medium.

According to the solutions of the disclosure, the environment configuration module may be provided to set, based on types or parameters or combinations of the types and the parameters of the plurality of layout units, a plurality of LPE environments, each corresponding to a respective one of the types, the parameters, or the combinations, and further extract the parasitic netlists of the plurality of layout cells in batches. As such, a user may extract the parasitic netlists of the plurality of layout cells in the automatically set environments in batches without performing complex environment setting manually. Therefore, time for parasitic parameter extraction may be reduced greatly, and furthermore, less time is needed by the post-simulation of a circuit.

A plenty of specific details are presented in the following description so as to provide a more thorough understanding of the disclosure. However, it is apparent to those skilled in the art that the disclosure may be implemented without one or more of these details. In other examples, some known technical features in the art are not described, so as to avoid confusion with the disclosure. That is, descriptions about some features of practical embodiments and detailed descriptions about known functions and structures are omitted herein.

In addition, the drawings only schematically illustrate the disclosure, and are not necessarily drawn to scale. The same reference numerals in the drawings represent the same or similar parts, and thus repeated descriptions about them are omitted. Some block diagrams shown in the drawings show function entities, which do not necessarily correspond to physically or logically independent entities. These function entities may be implemented in a software form. Alternatively, these function entities are implemented in one or more hardware modules or integrated circuits. Alternatively, these function entities are implemented in different networks and/or processor devices and/or microcontroller devices.

The flowcharts shown in the drawings are only exemplary descriptions, and do not necessarily include all the operations. For example, some operations may further be split, while some operations may be combined or partially combined. Therefore, the practical execution sequence may be changed according to an actual situation.

The terms used herein are only for the purpose of describing specific embodiments and not intended to limit the disclosure. As used herein, singular forms “a/an”, “one”, and “the/said” are also intended to include plural forms, unless otherwise specified in the context. It is also to be understood that, when terms “composed of” and/or “including” are used in the description, the existence of the features, integers, steps, operations, elements, and/or components is determined, but the existence or addition of one or more other features, integers, steps, operations, elements, components, and/or groups is not excluded. As used herein, term “and/or” includes any and all combinations of related listed items.

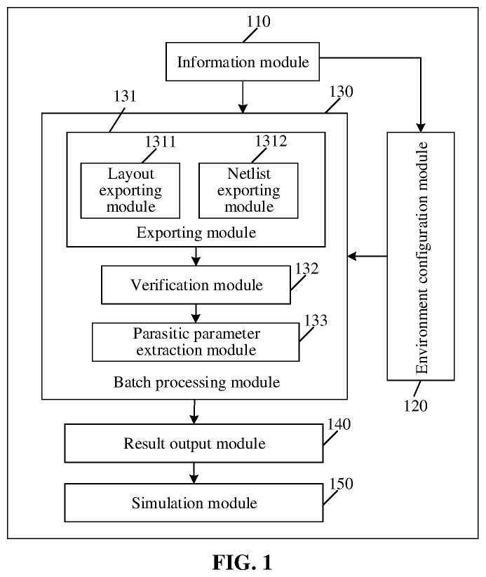

FIG. 1 is a schematic diagram of program modules of an apparatus for analyzing a circuit according to an embodiment of the disclosure. The apparatus includes an information module 110, an environment configuration module 120, and a batch processing module 130.

The information module 110 is configured to obtain a plurality of layout cells.

The environment configuration module 120 is configured to set, based on types or parameters or combinations of the types and the parameters of the plurality of layout units, a plurality of LPE environments, each corresponding to a respective one of the types, the parameters, or the combination.

The batch processing module 130 is configured to, for each of the LPE environments, extract parasitic parameter netlists of more than one of the plurality of layout units in the LPE environment in batches.

According to the solution of the embodiment of the disclosure, the environment configuration module may be provided to set, based on types or parameters or combinations of the types and the parameters of the plurality of layout units, a plurality of LPE environments, each corresponding to a respective one of the types, the parameters, or the combinations, and further extract the parasitic netlists of the plurality of layout cells in batches. As such, a user may extract the parasitic netlists of the plurality of layout cells in the automatically set LPE environment in batches without performing complex environment setting manually. Therefore, time for parasitic parameter extraction may be reduced greatly, and furthermore, less time is needed by the post-simulation of a circuit.

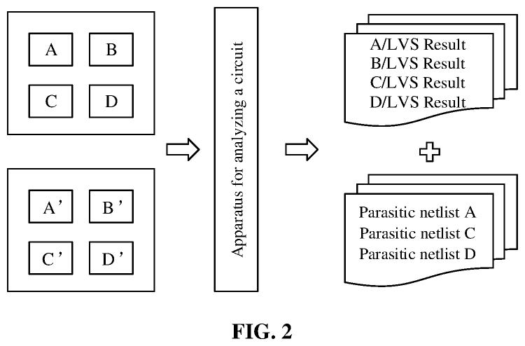

In order to understand the embodiment of the disclosure better, references are made to FIG. 2. FIG. 2 is a schematic diagram of a circuit analysis process according to an embodiment of the disclosure. In FIG. 2, a circuit layout includes multiple layout cells A, B, C, and D, and a schematic circuit diagram includes multiple circuit units A′, B′, C′, and D′ corresponding to the multiple layout cells. It is to be noted that the parasitic parameter netlist is practically of a flat and non-hierarchical structure, and unit layers in the figure are only to describe a logic structure thereof. Here, both the circuit units and the layout cells are obtained by the information module 110 in batches.

In some embodiments, the batch processing module 130 includes an exporting module 131. The exporting module 131 is configured to export Graphic Data System (GDS) files of the layout cells in a GDS exporting environment in batches and export circuit netlists of circuit units in a netlist exporting environment in batches. Here, both the GDS exporting environment and the netlist exporting environment are set by the environment configuration module 120 based on the type and/or parameter of the layout cell. Here, the GDS file is a file in a GDS format.

In some other embodiments, the exporting module 131 may include a layout exporting module 1311 and a netlist exporting module 1312. The layout exporting module 1311 is configured to export GDS files of the layout cells in a GDS exporting environment in batches. The netlist exporting module 1312 is configured to export circuit netlists of circuit units in a netlist exporting environment in batches.

Here, the GDS file of the layout cell represents a designed integrated circuit layout. The integrated circuit layout includes physical information of each device or hardware unit of a designed integrated circuit. The physical information may be shape, area, and position information of each device or hardware unit on a chip. The circuit netlist corresponding to the circuit unit represents a text file describing logic information between circuit elements, i.e., a connection relationship between the circuit elements, including connecting line information between various device units of the designed integrated circuit.

In some embodiments, the information module 110 may obtain multiple layout cells at one time. In other words, the information module 110 may obtain the layout cells in batches. Then, the environment configuration module 120 set LPE environments corresponding to the multiple layout cells one by one. The batch processing module 130 simultaneously extract parasitic parameter netlists of the multiple layout cells in the LPE environments set by the environment configuration module 120 in batches.

In some other embodiments, the information module 110 may obtain multiple layout cells at one time. In other words, the information module 120 may obtain the layout cells in batches. Then, the environment configuration module 120 set LPE environments corresponding to the multiple layout cells one by one. The batch processing module 130 extract parasitic parameter netlists of the corresponding layout cells one by one in the LPE environments set by the environment configuration module 120.

In some embodiments, the environment configuration module 120 is further configured to set a verification environment. The batch processing module 130 further includes a verification module 132. The verification module 132 is configured to perform Layout Versus Schematic (LVS) in the verification environment based on the GDS files and the circuit netlists.

Here, LVS mainly verifies whether circuit structures of the integrated circuit layout and the schematic circuit diagram, i.e., the circuit netlist, are consistent. The obtained GDS file and circuit netlist are input to the verification module 132. The verification module 132 verifies whether circuit structures of the GDS file and the circuit netlist are consistent. In this process, the verification module 132 may establish a one-to-one correspondence between physical information in the GDS file and logic information in the circuit netlist. After verification, the verification module 132 may output a verification result and a data file including the one-to-one correspondence between the physical information and the logic information. Here, a result of LVS includes the verification result and the data file.

In the embodiment of the disclosure, the verification result includes passed verification and failed verification. Passed verification represents that the circuit structures of the GDS file and the circuit netlist are correct in LVS. Failed verification represents that the circuit structures of the GDS file and the circuit netlist are incorrect in LVS. It is to be noted herein that, in the embodiment of the disclosure, the data file output by the verification module 132 is a data file obtained in case of passed verification. The data file includes physical information of each device unit and its corresponding connecting line information.

In the embodiment of the disclosure, the batch processing module 130 includes a parasitic parameter extraction module 133. The parasitic parameter extraction module 133 is configured to extract the parasitic parameter netlists of the multiple layout cells in the LPE environments in batches.

It is to be noted that, in the embodiment of the disclosure, the parasitic parameter extraction module 133 only extracts, based on the verification results and data files output by the verification module 132, the parasitic parameter netlist of a layout cell of which the circuit structures of the GDS file and the netlist are correct in LVS.

In a design process for manufacturing an integrated circuit, a physical design of the integrated circuit may describe specific geometric elements, generally referred to as a “layout” design. The geometric elements define shapes to be created in various materials so as to manufacture the integrated circuit. Generally, geometric element groups representing assemblies of circuit devices, such as contacts and gates, may be selected and placed in design regions. These geometric element groups may be customized, or selected from a pre-created design library, or determined in some combination of both manners. After the geometric element groups representing the assemblies of circuit devices are placed, geometric elements representing connecting lines are placed between these geometric elements according to predetermined lines. These connecting lines may form wirings for interconnecting electronic devices. Generally, a final layout design of the integrated circuit may be analyzed extensively. For example, the layout design may be analyzed to confirm that it represents circuit devices and relationships thereof described in the logic design of the integrated circuit accurately. The layout design may further be analyzed to confirm that it meets various design requirements, such as a minimum distance between the geometric elements. Furthermore, the layout design may be modified to use a redundant geometric element or add correction features to various geometric elements, so as to counteract restrictions in manufacturing, etc. During physical design analysis, the layout design may be analyzed to determine a parasitic parameter value of a network in the layout design, such as a parasitic capacitance, a parasitic resistance, and a parasitic inductance, which may be used to determine whether the layout design has a voltage drop, a signal delay, or a signal noise.

Here, parasitic parameter extraction is performed according to the data file output by the verification module 132 to obtain a parasitic parameter netlist corresponding to the designed integrated circuit. The parasitic parameter netlist includes multiple pieces of parasitic parameter information. The multiple pieces of parasitic parameter information may include parasitic parameter information corresponding to each device unit and/or parasitic parameter information of each connecting line (wire). Each device unit or wire may correspond to one or more pieces of parasitic parameter information. The parasitic parameter information includes a parasitic parameter attribute (such as parasitic resistance, parasitic capacitance, or parasitic inductance), as well as a parasitic parameter value (such as a parasitic resistance value, a parasitic capacitance value, and a parasitic inductance value). In the parasitic parameter netlist, each device unit or line is associated with the corresponding parasitic parameter attribute and parasitic parameter value thereof. Here, the parasitic parameter may be in a Standard Parasitic File (SPF) format.

In some embodiments, the environment configuration module 120 is connected to at least one set of Electronic Design Automation (EDA) software. The environment configuration module 120 configures the GDS exporting environment, the netlist exporting environment, the verification environment, and the LPE environment automatically by calling an interface of the at least one set of the EDA software.

In some embodiments, the environment configuration module 120 is connected to a plurality of sets of EDA software of different types. The environment configuration module 120 configures different types of GDS exporting environments, netlist exporting environments, verification environments, and LPE environments automatically by calling interfaces of the different sets of EDA software.

Here, EDA refers to designing and simulating the performance of an electronic circuit on the integrated circuit by use of a computer. EDA may be used to complete the design of a complex semiconductor integrated circuit. In the design of the integrated circuit, a connection relationship between various components of the circuit may be detected by EDA, thereby testing and verifying whether the integrated circuit operates properly.

In the embodiment of the disclosure, the environment configuration module may configure environments (including the GDS exporting environment, the netlist exporting environment, the verification environment, and the LPE environment) in a parasitic parameter extraction process automatically based on the types and/or parameters of the layout cells, thereby avoiding the manual configuration of the user.

In some embodiments, the apparatus for analyzing a circuit further includes: a result output module 140, configured to generate a report of the plurality of layout cells according to verification results of the LVS and the parasitic parameter netlists. The report extracts batch processing results of all the layout cells, including error types and counts, parasitic parameter netlists, etc., involved in failed verification, and is presented to the user visually.

Referring to FIG. 2, after the apparatus for analyzing a circuit provided in the embodiment of the disclosure performs batch processing on the multiple layout cells, the layout cells A, C, and D pass LVS, while the layout cell B does not pass LVS. Parasitic parameters of the layout cells A, C, and D passing LVS are extracted to obtain parasitic parameter netlists of the layout cells A, C, and D. Finally, a report of the plurality of layout cells is generated according to results of the LVS and the parasitic parameter netlists. It is to be noted that, for a layout cell not passing verification, a layout engineer needs to correct the layout cell.

In some embodiments, the apparatus for analyzing a circuit further includes: a simulation module 150, configured to perform post-simulation according to the parasitic parameter netlists.

Here, post-simulation refers to back-annotating the parasitic parameter, such as the parasitic resistance, the parasitic capacitance, or the parasitic inductance, in the parasitic parameter netlist into the extracted circuit netlist for simulation and analyzing the integrated circuit to ensure that the integrated circuit meets a design requirement.

In some embodiments, the information module 110 includes: a Graphical User Interface (GUI), configured to obtain the layout cells. In the embodiment of the disclosure, after the user inputs specified information through the GUI, the apparatus for analyzing a circuit may perform batch parasitic parameter extraction on multiple layout cells included in the specified information rapidly to obtain parasitic parameter netlists, and then perform batch post-simulation according to the parasitic parameter netlists.

According to the solution of the embodiment of the disclosure, the environment configuration module may be provided to set, based on types or parameters or combinations of the types and the parameters of the plurality of layout units, a plurality of LPE environments, each corresponding to a respective one of the types, the parameters, or the combinations, and further extract the parasitic netlists of the plurality of layout cells in batches. As such, a user may extract the parasitic netlists of the plurality of layout cells in the automatically set environments in batches without performing complex environment setting manually. Therefore, time for parasitic parameter extraction may be reduced greatly, and furthermore, less time is needed by the post-simulation of a circuit.

The exemplary solution or technology according to the embodiment of the disclosure may be applied to an integrated circuit layout of a memory. Here, the memory may be a volatile memory, such as a Dynamic Random Access Memory (DRAM). Alternatively, the memory may be a non-volatile memory, such as a Read-Only Memory (ROM), a Programmable ROM (PROM), an Erasable PROM (EPROM), an Electrically EPROM (EEPROM), a Phase-change Random Access Memory (PRAM), a Magnetic Random Access Memory (MRAM), a Resistive Random Access Memory (RRAM), and a Ferroelectric Random Access Memory (FRAM).

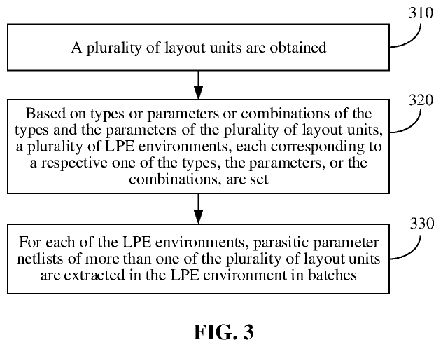

Based on the above-mentioned apparatus for analyzing a circuit, an embodiment of the disclosure also provides a method for analyzing a circuit. FIG. 3 is a schematic diagram of an implementation process of a method for analyzing a circuit according to an embodiment of the disclosure. As shown in FIG. 3, the method for analyzing a circuit includes the following operations.

In operation 310, a plurality of layout cells are obtained.

In operation 320, based on types or parameters or combinations of the types and the parameters of the plurality of layout units, a plurality of LPE environments, each corresponding to a respective one of the types, the parameters, or the combinations, are set.

In operation 330, for each of the LPE environments, parasitic parameter netlists of more than one of the plurality of layout units are extracted in the LPE environment in batches.

In some embodiments, the operation that based on types or parameters or combinations of the types and the parameters of the plurality of layout units, a plurality of LPE environments, each corresponding to a respective one of the types, the parameters, or the combinations, are set includes that: the LPE environments automatically are configured by calling an interface of a set of EDA software.

In some embodiments, the operation that based on types or parameters or combinations of the types and the parameters of the plurality of layout units, a plurality of LPE environments, each corresponding to a respective one of the types, the parameters, or the combinations, are set includes that: different types of the LPE environments are configured automatically by calling interfaces of sets of different EDA software.

In some embodiments, before the operation that parasitic parameter netlists of more than one of the plurality of layout units are extracted in the LPE environment in batches, the circuit method for analyzing a circuit further includes the following operation.

A GDS exporting environment is set, and GDS files of the plurality of the layout cells are exported in the GDS exporting environment in batches.

In some embodiments, the operation that based on types or parameters or combinations of the types and the parameters of the plurality of layout units, a plurality of LPE environments, each corresponding to a respective one of the types, the parameters, or the combinations, are set includes that: a netlist exporting environment is set.

The operation that the plurality of layout cells are obtained includes that: circuit units, each corresponding to a respective one of the plurality of layout cells, are obtained.

The method further includes that: circuit netlists of the circuit units are exported in the netlist exporting environment in batches.

In some embodiments, the operation that based on types or parameters or combinations of the types and the parameters of the plurality of layout units, a plurality of LPE environments, each corresponding to a respective one of the types, the parameters, or the combinations, are set includes that: a verification environment is set.

The method for analyzing a circuit further includes that: LVS is performed in the verification environment based on the GDS files and the circuit netlists.

In some embodiments, the method for analyzing a circuit further includes that: a report of the plurality of layout cells is generated according to verification results of the LVS and the parasitic parameter netlists.

In some embodiments, the method for analyzing a circuit further includes: post-simulation is performed according to the parasitic parameter netlists.

With respect to the method for analyzing a circuit in the above-mentioned embodiments, specific steps of the operations in each step have been described in detail in the embodiments about the apparatus for analyzing a circuit, and will not be described in detail herein.

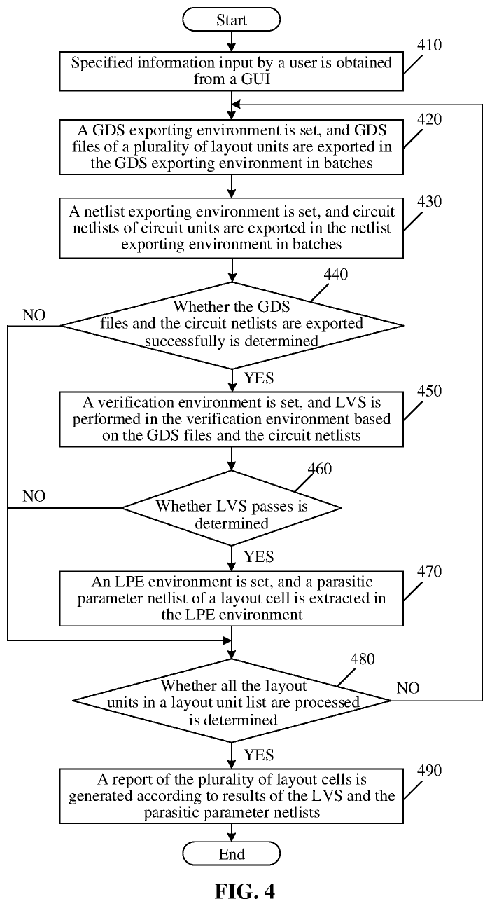

FIG. 4 a schematic diagram of an implementation process of a parasitic parameter extraction method according to a specific example of the disclosure. As shown in FIG. 4, the method includes the following operations.

In operation 410, specified information input by a user is obtained from a GUI.

In the embodiment of the disclosure, the specified information includes a layout cell list, a layout library, and a circuit library, etc. The layout cell list includes information about multiple layout cells. After the layout cell list is obtained from the GUI, a respective layout cell is obtained from the layout library based on the information (such as an Identifier (ID)) of each of the layout cells in the layout cell list, and multiple circuit units corresponding to the multiple layout cells are obtained from the circuit library.

In operation 420, a GDS exporting environment is set, and GDS files of a plurality of layout cells are exported in the GDS exporting environment in batches.

In the embodiment of the disclosure, the multiple layout cells in the layout cell list may be processed one by one. Alternatively, the multiple layout cells in the layout cell list may be processed in batches. Alternatively, the multiple layout cells in the layout cell list may be processed simultaneously in batches.

Here, the GDS file of the layout cell represents a designed integrated circuit layout. The integrated circuit layout includes physical information of each device or hardware unit of a designed integrated circuit. The physical information may be shape, area, and position information of each device or hardware unit on a chip.

In operation 430, a netlist exporting environment is set, and circuit netlists of circuit units are exported in the netlist exporting environment in batches.

In operation 440, whether the GDS files and the circuit netlists are exported successfully is determined.

Here, the circuit netlist corresponding to the circuit unit represents a text file describing logic information between circuit elements, i.e., a connection relationship between the circuit elements, including connecting line information between various device units of the designed integrated circuit.

In the embodiment of the disclosure, if a determining result is that the GDS files and the circuit netlists are exported successfully, operation S450 is performed. If the determining result is that the GDS files and the circuit netlists are not successfully exported, operation S480 is performed.

In operation 450, a verification environment is set, and LVS is performed in the verification environment based on the GDS files and the circuit netlists.

In operation 460, whether the LVS passes is determined.

Here, LVS mainly verifies whether circuit structures of the integrated circuit layout and the schematic circuit diagram, i.e., the circuit netlist, are consistent. Whether circuit structures of the obtained GDS file and circuit netlist are consistent is verified. In this process, a one-to-one correspondence between the physical information in the GDS file and the logic information in the circuit netlist is established. After verification, a verification result and a data file including the one-to-one correspondence between the physical information and the logic information are output. Here, a result of LVS includes the verification result and the data file.

In the embodiment of the disclosure, the verification result includes passed verification and failed verification. Passed verification represents that the circuit structures of the GDS file and the circuit netlist are correct in LVS. Failed verification represents that the circuit structures of the GDS file and the circuit netlist are incorrect in LVS.

In the embodiment of the disclosure, if a determining result is that LVS passes, operation S470 is performed. If the determining result is that LVS fails, operation S480 is performed.

In operation 470, an LPE environment is set, and a parasitic parameter netlist of a layout cell is extracted in the LPE environment. Here, parasitic parameter extraction is performed on the layout cell to obtain a parasitic parameter netlist corresponding to the designed integrated circuit. The parasitic parameter netlist includes multiple pieces of parasitic parameter information. The multiple pieces of parasitic parameter information may include parasitic parameter information corresponding to each device unit and/or parasitic parameter information of each connecting line (wire). Each device unit or wire may correspond to one or more pieces of parasitic parameter information. The parasitic parameter information includes a parasitic parameter attribute (such as parasitic resistance or parasitic capacitance), as well as a parasitic parameter value (such as a parasitic resistance value and a parasitic capacitance value). In the parasitic parameter netlist, each device unit or line is associated with the corresponding parasitic parameter attribute and parasitic parameter value thereof.

In operation 480, whether all the layout cells in a layout cell list are processed is determined.

In the embodiment of the disclosure, if a determining result is that all the layout cells in the layout cell list are processed, operation S490 is performed. If the determining result is that not all the layout cells in the layout cell list are processed, operation S420 is performed, and unprocessed layout cells in the layout cell list continue to be processed.

In operation 490, a report of the plurality of layout cells is generated according to results of the LVS and the parasitic parameter netlists.

In the embodiment of the disclosure, the report extracts batch processing results of all the layout cells, including error types and counts, parasitic parameter netlists, etc., involved in failed verification, and is presented to the user visually.

With respect to the parasitic parameter extraction method in the above-mentioned embodiments, specific steps of the operations in each step have been described in detail in the embodiments about the apparatus for analyzing a circuit, and will not be described in detail herein.

According to the parasitic parameter extraction method provided in the embodiments of the disclosure, parasitic parameters of multiple layout cells may be extracted in batches. Furthermore, based on types or parameters or combinations of the types and the parameters of the plurality of layout units, a plurality of environments, each corresponding to a respective one of the types, the parameters, or the combinations may be set in each of various processes (GDS exporting, netlist exporting, LVS, and LPE), thereby avoiding the manual setting of the user.

Each module in the apparatus for analyzing a circuit may completely or partially be implemented by software, hardware, and a combination thereof. Each module may be embedded in a hardware form into or independent of a processor in a computer device, or may be stored in a software form in a memory in the computer device, for the processor to call to execute the operations corresponding to each module.

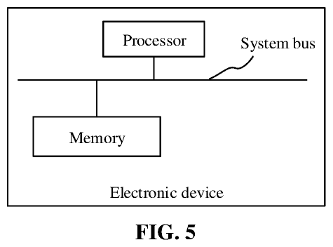

In order to understand the embodiments of the disclosure better, references are made to FIG. 5. FIG. 5 is schematic diagram of a hardware structure of an electronic device according to an embodiment of the disclosure. As shown in FIG. 5, the electronic device according to an embodiment of the disclosure includes: a memory, configured to store a computer program; and a processor, configured to execute the computer program in the memory to implement each operation in the method for analyzing a circuit described in the above-mentioned embodiments, specifically referring to the related descriptions in the method embodiments. Elaborations are omitted in this embodiment.

Optionally, the memory may be independent, or may be integrated with the processor. When the memory is arranged independently, the device further includes: a bus, configured to connect the memory to the processor.

Based on the contents described in the above-mentioned embodiments, an embodiment of the disclosure also provides a computer-readable storage medium storing computer-executable instructions, which, when being executed by a processor to implement each operation of the method for analyzing a circuit described in the above-mentioned embodiments, specifically referring to the related descriptions in the method embodiments. Elaborations are omitted in this embodiment.

It can be understood that the same or similar parts in each of the above-mentioned embodiments may refer to each other, and contents not described in detail in some embodiments may refer to the same or similar contents in the other embodiments.

It is to be noted that, in the descriptions of the disclosure, terms “first”, “second”, etc., are only for a purpose of description and cannot be understood as indicating or implying relative importance. In addition, in the descriptions of the disclosure, “a plurality of/multiple” means at least two, unless otherwise stated.

Any process or method in the flowcharts or described herein in another manner may be understood as representing a module, segment, or part including codes of one or more executable instructions for realizing specific logic functions or operations of the process. Moreover, the scope of the preferred implementations of the disclosure includes other implementations, in a sequence different from the shown or discussed sequence, including the execution of the functions basically simultaneously or in an opposite sequence according to the involved functions. This should be understood by those skilled in the art the embodiments of the disclosure belong to.

It is to be understood that each part of the disclosure may be implemented by means of hardware, software, firmware, or a combination thereof. In the above-mentioned implementations, multiple operations or methods may be implemented by means of software or firmware stored in a memory and executed by an appropriate instruction execution system. For example, if implemented by means of hardware, as in another embodiment, it can be implemented by means of any one or a combination of the following techniques commonly known in the art: a discrete logical circuit having a logical gate circuit used for implementing a logical function for a data signal, an application-specific integrated circuit having an appropriate combinational logical gate circuit, a Programmable Gate Array (PGA), a Field-Programmable Gate Array (FPGA), etc.

It should be noted that those skilled in the art may understand all or some of the processes in the methods of the embodiments described above can be implemented by using programs to instruct corresponding hardware. The programs may be stored in a computer readable storage medium. When the programs are executed, one or combinations of the processes in the methods of the above embodiments may be performed.

In addition, in various embodiments of the present disclosure, the functional units may be integrated in one processing module, or may separately and physically exist, or two or more units may be integrated in one module. The above-mentioned integrated module may be implemented by hardware, or may be implemented by software functional modules. When the integrated module is implemented in the form of software functional modules and sold or used as independent products, the integrated module may be stored in a computer-readable storage medium.

The storage medium may be a ROM, a magnetic disk, an optical disk, or the like.

In the description, descriptions made with reference to terms “an embodiment”, “some embodiments”, “example”, “specific example”, “some examples”, or the like refer to that specific features, structures, materials, or characteristics described in combination with the embodiment or the example are included in at least one embodiment or example of the disclosure. In the description, schematic expressions about these terms are not necessarily for the same embodiment or example. Moreover, the described specific features, structures, materials, or characteristics may be combined as appropriate in any one or more embodiments or examples.

The above is only the specific implementation modes of the disclosure and not intended to limit the scope of protection of the disclosure. Any variations or replacements apparent to those skilled in the art within the technical scope disclosed in the disclosure shall fall within the scope of protection of the disclosure. Therefore, the scope of protection of the disclosure shall be subject to the scope of protection of the claims.

According to the solutions of the disclosure, the environment configuration module may be provided to set, based on types or parameters or combinations of the types and the parameters of the plurality of layout units, a plurality of LPE environments, each corresponding to a respective one of the types, the parameters, or the combinations, and further extract the parasitic netlists of the plurality of layout cells in batches. As such, a user may extract the parasitic netlists of the plurality of layout cells in the automatically set environments in batches without performing complex environment setting manually. Therefore, time for parasitic parameter extraction may be reduced greatly, and furthermore, less time is needed by the post-simulation of a circuit.

What is claimed is:

1. An apparatus for analyzing a circuit, comprising:
an information circuit, configured to obtain a plurality of layout cells;
an environment configuration circuit, configured to set, based on types or parameters or combinations of the types and the parameters of the plurality of layout units, a plurality of Layout Parasitic Extraction (LPE) environments, each corresponding to a respective one of the types, the parameters, or the combinations; and
a batch processing circuit, configured to, for each of the LPE environments, extract parasitic parameter netlists of more than one of the plurality of layout units in the LPE environment in batches.

2. The apparatus of claim 1, wherein the environment configuration circuit is connected to at least one set of Electronic Design Automation (EDA) software, and is configured to configure the LPE environments automatically by calling an interface of the at least one set of EDA software.

3. The apparatus of claim 2, wherein the environment configuration circuit is connected to a plurality of sets of the EDA software of different types, and is configured to configure different types of the LPE environments automatically by calling interfaces of different sets of EDA software.

4. The apparatus of claim 1, wherein the environment configuration circuit is further configured to set a Graphic Data System (GDS) exporting environment, and the batch processing circuit comprises an exporting circuit being configured to export GDS files of the plurality of layout cells in the GDS exporting environment in batches.

5. The apparatus of claim 4, wherein the information circuit is further configured to obtain circuit units, each corresponding to a respective one of the plurality of layout cells, the environment configuration circuit is further configured to set a netlist exporting environment, and the exporting circuit is further configured to export circuit netlists of the plurality of the circuit units in the netlist exporting environment in batches.

6. The apparatus of claim 5, wherein the environment configuration circuit is further configured to set a verification environment, and the batch processing circuit further comprises a verification circuit being configured to perform Layout Versus Schematic (LVS) in the verification environment based on the GDS files and the circuit netlists.

7. The apparatus of claim 6, further comprising: a result output circuit, configured to generate a report of the plurality of layout cells according to verification results of the LVS and the parasitic parameter netlists.

8. The apparatus of claim 1, wherein the information circuit comprises a Graphical User Interface (GUI) being configured to obtain the plurality of layout cells.

9. The apparatus of claim 1, further comprising: a simulation circuit, configured to perform post-simulation according to the parasitic parameter netlists output by the batch processing circuit.

10. A method for analyzing a circuit, comprising:
obtaining a plurality of layout units;
setting, based on types or parameters or combinations of the types and the parameters of the plurality of layout units, a plurality of Layout Parasitic Extraction (LPE) environments, each corresponding to a respective one of the types, the parameters, or the combinations; and
for each of the LPE environments, extracting parasitic parameter netlists of more than one of the plurality of layout units in the LPE environment in batches.

11. The method of claim 10, wherein the setting, based on types or parameters or combinations of the types and the parameters of the plurality of layout units, the plurality of LPE environments, each corresponding to the respective one of the types, the parameters, or the combinations comprises: configuring the LPE environments automatically by calling an interface of a set of Electronic Design Automation (EDA) software.

12. The method of claim 11, wherein the setting, based on types or parameters or combinations of the types and the parameters of the plurality of layout units, the plurality of LPE environments, each corresponding to the respective one of the types, the parameters, or the combinations comprises: configuring different types of the LPE environments automatically by calling interfaces of different sets of EDA software.

13. The method of claim 10, further comprising:
before the extracting parasitic parameter netlists of more than one of the plurality of layout units in the LPE environment in batches, setting a Graphic Data System (GDS) exporting environment, and exporting GDS files of the plurality of layout cells in the GDS exporting environment in batches.

14. The method of claim 13, wherein the setting, based on types or parameters or combinations of the types and the parameters of the plurality of layout units, the plurality of LPE environments, each corresponding to the respective one of the types, the parameters, or the combinations comprises: setting a netlist exporting environment;
the obtaining the plurality of layout cells comprises: obtaining circuit units, each corresponding to a respective one of the plurality of layout cells; and
the method further comprises: exporting circuit netlists of the plurality of the circuit units in the netlist exporting environment in batches.

15. The method of claim 14, wherein the setting, based on types or parameters or combinations of the types and the parameters of the plurality of layout units, the plurality of LPE environments, each corresponding to the respective one of the types, the parameters, or the combinations further comprises:
setting a verification environment; and
the method further comprises: performing Layout Versus Schematic (LVS) in the verification environment based on the GDS files and the circuit netlists.

16. The method of claim 15, further comprising:
generating a report of the plurality of layout cells according to verification results of the LVS and the parasitic parameter netlists.

17. The method of claim 10, further comprising:
performing post-simulation according to the parasitic parameter netlists.

18. An electronic device, comprising:
a memory, configured to store a computer program; and
a processor, configured to execute the computer program in the memory,
wherein the processor is configured to:
obtain a plurality of layout cells;
set, based on types or parameters or combinations of the types and the parameters of the plurality of layout units, a plurality of Layout Parasitic Extraction (LPE) environments, each corresponding to a respective one of the types, the parameters, or the combinations; and
for each of the LPE environments, extract parasitic parameter netlists of more than one of the plurality of layout units in the LPE environment in batches.

19. The electronic device of claim 18, wherein the processor is configured to: configure the LPE environments automatically by calling an interface of the at least one set of Electronic Design Automation (EDA) software, or configure different types of the LPE environments automatically by calling interfaces of different sets of EDA software.

20. The electronic device of claim 18, wherein the processor is further configured to:
before extracting parasitic parameter netlists of more than one of the plurality of layout units in the LPE environment in batches, set a Graphic Data System (GDS) exporting environment, and export GDS files of the plurality of layout cells in the GDS exporting environment in batches.
